(19) United States
(12) Patent Application Publication
(10) Pub. No.: US 2012/0081628 A1
(43) Pub. Date: Apr. 5, 2012

(54) LIQUID CRYSTAL DISPLAY DEVICE AND MANUFACTURING METHOD THEREOF

(75) Inventors: Hidekazu NITTA, Chiba (JP); Hidekazu Miyake, Mobara (JP); Takuo Kaitoh, Mobara (JP)

(73) Assignees: Panasonic Liquid Crystal Display Co., Ltd.; Hitachi Displays, Ltd.

(21) Appl. No.: 13/252,478

(22) Filed: Oct. 4, 2011

(30) Foreign Application Priority Data
Oct. 5, 2010 (JP) 2010-225623

(51) Int. Cl. G02F 1/136; H01L 33/62

(52) U.S. Cl. 349/43; 438/34; 257/E33.062

(57) ABSTRACT

A liquid crystal display device intended for increasing the ON-current of a TFT in the pixel while suppressing variation of the ON-current, in which a semiconductor layer and a first n⁺-a-Si layer in the TFT are formed continuously by plasma CVD. The semiconductor layer and the first n⁺-a-Si layer are patterned simultaneously. Then, a second n⁺-a-Si layer is formed so as to cover the upper surface of the first n⁺-a-Si layer and the side portion of the semiconductor layer. The ON-current can be increased and variation of the ON-current of the TFT can be decreased by forming the first n⁺-a-Si layer continuously over the semiconductor layer.

### CLAIM OF PRIORITY

The present application claims priority from Japanese Patent Application JP 2010-225623 filed on Oct. 5, 2010, the content of which is hereby incorporated by reference into this application.

### BACKGROUND OF THE INVENTION

1. Field of the Invention

The present invention relates to a liquid crystal display device. More particularly, the invention relates to a liquid crystal display device in which a thin film transistor has a high ON-current for pixel control, quick writing of video signals are achieved, and there is less variation in ON-current characteristics.

2. Description of the Related Art

A liquid crystal panel for use in a liquid crystal display device includes a TFT substrate having pixel electrodes, thin film transistors (TFT), or the like formed thereon in a matrix form, and a counter electrode opposing the TFT substrate and having color filters, or the like formed at positions corresponding to the pixel electrodes of the TFT substrate. Liquid crystals are put between the TFT substrate and the counter substrate. The liquid crystal display device controls light transmittance for each pixel by using liquid crystal molecules to form images.

The number of pixels has increased in the screen of the liquid crystal device due to enlargement in the size thereof and high definition. Since, in such a case, the frequency at which video signals are written in one frame increases, the time it takes for writing video signals to each pixel is restricted. For enabling short-time writing to each pixel, the ON-current of a TFT in the pixel needs to be increased while the OFF-current of the TFT needs to be kept small.

To address the problems as described above, JP-A-11-17188 describes a configuration in which a contact portion between a semiconductor layer formed of a-Si that operates as an active layer of a TFT and a drain electrode or a source electrode is formed by two layers of a n⁺-a-Si layer and a n⁺-poly-Si (microcrystalline silicon) layer.

### SUMMARY OF THE INVENTION

In the technique described in JP-A-11-17188, different kinds of semiconductors such as the n⁺-a-Si layer and the n⁺-poly-Si layer have to be formed between a semiconductor layer 103 and a drain electrode 107 or a source electrode 108. Thus the relevant process is difficult to control.

As a technique for increasing the ON-current of the TFT, a technique has been developed for forming a n⁺-a-Si layer not only on the upper surface a semiconductor layer 103 but also on the side of the semiconductor layer 103. The semiconductor 103 comprises an a-Si layer. Such a configuration, which is shown in FIG. 10, is referred to as a side wall TFT.

A liquid crystal display device is formed by putting a liquid crystal layer between a TFT substrate 100 and a counter substrate. FIG. 10 is a cross sectional view of the TFT substrate 100. For the TFT substrate 100 shown in FIG. 10, an alignment film is not shown.

In FIG. 10, a n⁺-a-Si layer covers the upper surface and the side of a semiconductor layer 103. Since, in such a structure, the ON-current of a TFT can flow also on the side of the semiconductor layer 103, the ON-current can be increased. In contrast, the OFF-current of the TFT can be kept at an existent level.

A process for forming the TFT substrate 100 shown in FIG. 10 is to be shown with reference to FIG. 11 to FIG. 16. Referring to FIG. 11, a gate electrode 101 is formed on a TFT substrate 100 formed of glass, a gate insulating film 102 is formed to cover a gate electrode 101, and a semiconductor layer 103 comprising a-Si is formed on a gate insulating film 102 and over the gate electrode 101. Successively, the semiconductor layer 103 is patterned as shown in FIG. 12.

Subsequently, as shown in FIG. 13, a n⁺-a-Si layer is formed to cover the semiconductor layer 103 and the gate insulating film 102. n⁺-a-Si serves to provide ohmic contact between a drain electrode 107 and a source electrode 108 which are subsequent formed of a metal and semiconductor layer 103. The n⁺-a-Si layer covers not only the upper surface of semiconductor layer 103 but also the side of the semiconductor layer 103. This intends to increase the ON-current.

Then, as shown in FIG. 14, a metal layer 106 comprising, for example, MoCr is formed to cover the n⁺-a-Si layer for forming the drain electrode 107 and the source electrode 108. Successively, as shown in FIG. 15, the metal layer 106 is patterned by photolithography to form the drain electrode 107 and the source electrode 108.

Then, as shown in FIG. 15, the n⁺-a-Si layer is dry etched by using the drain electrode 107 and the source electrode 108 as a resist thereby patterning the n⁺-a-Si layer. In this step, the characteristic of a channel region is stabilized by etching also a portion of the semiconductor layer 103 at a region where the drain electrode 107 and the source electrode 108 are opposed. A removed region of the semiconductor layer is referred to as a channel etching 120.

Then, a passivation film 109 is coated over the entire TFT substrate 100 including a TFT. This is for protecting the TFT. A through hole 110 is formed in the passivation film 109 for connecting a pixel electrode 111 formed subsequently to the source electrode 108 of the TFT. Then, ITO (Indium Tin Oxide) as a transparent conductive film to form the pixel electrode 111 is deposited and ITO is patterned to form the pixel electrode 111.

The side wall TFT descried above involves a problem that the ON-current varies. This is considered to be the following phenomenon. The semiconductor layer 103 in FIG. 12 and the n⁺-a-Si layer in FIG. 13 are formed by plasma CVD. The plasma CVD is generated in one identical chamber.

The semiconductor layer 103 comprising a-Si is an i-type semiconductor. Since the characteristic of the semiconductor layer 103 fluctuates sensitively by an impurity, the inside of a chamber for plasma CVD is made clean by coating an insulator such as of SiN in the chamber before deposition of the semiconductor layer 103. That is, by covering the inside of the chamber with the insulator, intrusion of an impurity deposited on the wall of the chamber, etc. into the semiconductor layer 103 is prevented.

The coating operation described above is performed every time the semiconductor 103 is formed. That is, when the semiconductor 103 is deposited to one substrate, vacuum in the chamber is released and the substrate is taken out. An insulator is coated to the chamber to clean the inside of the chamber before plasma CVD is conducted in the chamber for other substrate.

Then, the amount of the laminate of the insulator film and the a-Si film is increased more for substrates processed later. Accordingly, the condition for forming the semiconductor layer 103 to the first substrate is different from that for forming the semiconductor layer 103 to the last substrate. Actually, this results in a phenomenon that the ON-current of the TFT varies on every substrate.

That is, in the past, while the ON-current of the TFT was large in a substrate over which the semiconductor layer 103 is first formed by plasma CVD, the ON-current was decreased for the substrates processed later. Such variation of the TFT characteristics is not desirable as characteristics for the entire liquid crystal display device.

On the other hand, when a thick insulator is coated in the chamber before plasma CVD processing, the ON-current of the formed TFT is decreased. However, the difference of the ON-current of the TFT depending on the processing order is decreased between each of the substrates undergoing the plasma CVD.

That is, both the substrate initially put to the plasma CVD and the substrate finally put to the plasma CVD are stabilized at a small ON-current. In the past, the insulator film was coated thickly in the chamber from the beginning for suppressing the variation of the ON-current. Accordingly, TFTs of small ON-current had to be used.

However, as the screen is enlarged in the size or increased in definition, the number of pixels is increased to result in restriction for the time of writing video signals. For making the writing of the video signal at a higher speed, it is necessary to increase the ON-current of the TFT. The present invention intends to increase the ON-current of a TFT, as well as suppress variation of the ON-current.

The present invention intends to solve the subject described above and specific means therefor is as described below. That is, after a semiconductor layer comprising a-Si is formed, a first n⁺-a-Si layer is formed thinly in one identical chamber continuously without breaking vacuum. The semiconductor layer is formed by plasma CVD in a phosphine atmosphere and the n⁺-a-Si layer is formed by plasma CVD in a phosphorus (P)-doped phosphine atmosphere.

The ON-current of the TFT is increased by the diffusion of phosphorus (P) doped in n⁺-a-Si into the semiconductor layer. On the other hand, the OFF-current is kept low as it is. In such a process, the amount of phosphorus (P) upon forming the first n⁺-a-Si layer can be controlled intentionally. Accordingly, the ON-current of the TFT can be increased and, at the same time, variation can be suppressed.

Subsequently, a substrate having a semiconductor layer and n⁺-a-Si stacked thereover is taken out of the chamber and patterned by etching. Then, a second n⁺-a-Si layer is formed by plasma CVD in a phosphorus (P)-doped phosphine atmosphere. The second n⁺-a-Si layer forms a side wall covering the side of the semiconductor layer to increase the ON-current. The subsequent process is identical with the usual process.

That is, according to the invention, a first n⁺-a-Si layer formed contiguous with and over the semiconductor layer and patterned at the same time, and a second n⁺-a-Si layer forming the side wall for increasing the ON-current are formed between the drain electrode and the source electrode.

According to the invention, since the semiconductor layer and the n⁺-a-Si layer are formed continuously by plasma CVD in one identical chamber, the ON-current characteristics of the semiconductor layer can be controlled stably. That is, the ON-current of the TFT can be maintained high while the variation thereof is restricted. Further, the OFF-current of the TFT can be kept low as usual.

Thus, the time for writing video signals can be shortened and, even when the number of pixels is increased due to enlargement in the size and increase in the definition of the screen, since signals can be written at high speed, image reproducibility can be maintained and display at high image quality can be attained.

### BRIEF DESCRIPTION OF THE DRAWINGS

FIG. 1 is a cross sectional view of a TFT substrate of a liquid crystal display panel according to the invention:

FIG. 2 is a cross sectional view for the first n⁺-a-Si layer in a TFT substrate up to a deposition step;

FIG. 3 is a cross sectional view showing the principle of the invention;

FIG. 4 is a cross sectional view showing a state in which a semiconductor layer and a first n⁺-a-Si layer are patterned;

FIG. 5 is a cross sectional view showing a state in which a second n⁺-a-Si layer is deposited;

FIG. 6 is a cross sectional view in which a metal film to form a drain electrode and a source electrode is deposited;

FIG. 7 is a cross sectional view in which the drain electrode and the source electrode are patterned;

FIG. 8 is a cross sectional view showing a state in which the second n⁺-a-Si layer is patterned and channel etching is performed;

FIG. 9 is a cross sectional view of a step of forming up to a pixel electrode in a TFT substrate of the invention;

FIG. 10 is a cross sectional view of a TFT substrate of an existent example with an alignment film omitted;

FIG. 11 is a cross sectional view of a step of depositing up to a semiconductor layer in the TFT substrate of the existent example;

FIG. 12 is a cross sectional view in which the semiconductor layer is patterned in the TFT substrate of the existent example;

FIG. 13 is a cross sectional view showing a state in which a side wall is formed by an n⁺-a-Si layer in the TFT substrate of the existent example;

FIG. 14 is a cross sectional view in which a metal film to form a drain electrode or a source electrode is deposited in a TFT substrate of the existent example;

FIG. 15 is a cross sectional view in which the drain electrode and the source electrode are formed by patterning the metal film in the TFT substrate of the existent example;

FIG. 16 is a cross sectional view in which a n⁺-a-Si layer is patterned in the TFT substrate of the existent example.

### DESCRIPTION OF THE PREFERRED EMBODIMENTS

The present invention will be described specifically with reference to examples.

### Example 1

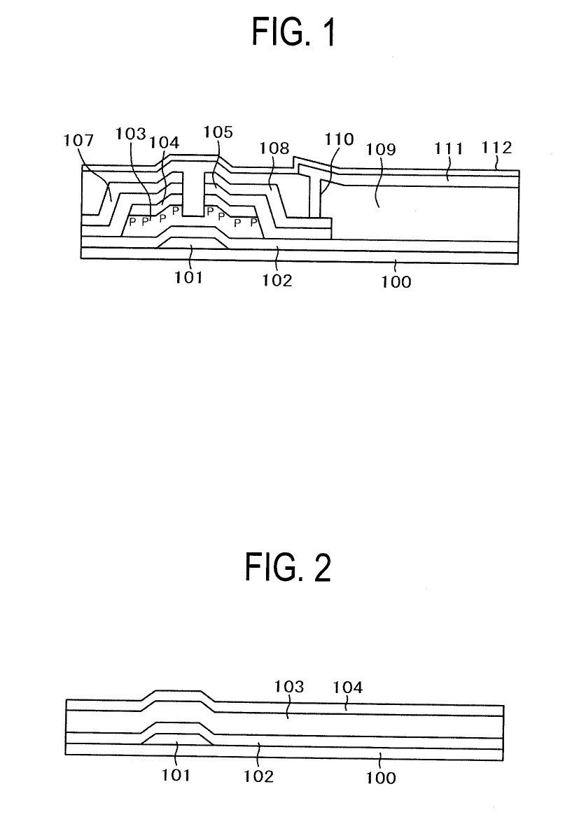

FIG. 1 is a cross sectional view of a TFT substrate 100 according to the present invention. A liquid crystal display device is formed by putting a liquid crystal between a TFT substrate 100 having a pixel electrode 111 and a TFT formed thereabove and a counter substrate having a color filter, etc. formed thereon. FIG. 1 is a cross sectional view for a portion of a TFT substrate 100 of the liquid crystal display device.

In FIG. 1, a gate electrode 101 is formed on a TFT substrate 100 made of glass. The gate electrode 101 is formed of, for example, MoCr and has a thickness of 150 to 200 nm. A gate insulating film 102 is formed to cover the gate electrode 101. The gate insulating film 102 is formed of, for example, SiN and has a thickness of about 300 nm.

A semiconductor layer 103 made of a-Si is formed on the gate insulating film 102 and over the gate electrode 101. The thickness of the semiconductor layer 103 is 150 to 200 nm. A first n⁺-a-Si layer 104 is formed on the semiconductor layer 103. Phosphorus (P) is doped to a-Si in the n⁺-a-Si layer.

The semiconductor layer 103 and the n⁺-a-Si layer are formed continuously by plasma CVD in one identical chamber without breaking vacuum. The thickness of the n⁺-a-Si layer is about 10 nm. The n⁺-a-Si layer serves to keep the surface of the semiconductor layer 103 always at a constant state and diffuse phosphorus (P) to the surface of the semiconductor layer 103 to increase the ON-current of the TFT.

A second n⁺-a-Si layer 105 is formed covering the semiconductor layer 103 and the first n⁺-a-Si layer 104. Phosphorus (P) is doped to a-Si also in the second n⁺-a-Si layer 105. The second n⁺-a-Si layer 105 forms a side wall covering the side of the semiconductor layer 103, with the layer 105 serving to increase the ON-current of the TFT. The thickness of the second n⁺-a-Si layer 105 is about 25 nm.

That is, the thickness of the first n⁺-a-Si layer 104 is smaller than that of the second n⁺-a-Si layer 105. Since the first n⁺-a-Si layer 104 serves to stably supply, to the surface of the semiconductor layer 103, phosphorus (P) doped to the first n⁺-a-Si layer 104 by a predetermined amount, the first n⁺-a-Si layer 104 need not be thick. In contrast, the second n⁺-a-Si layer 105 need have a predetermined thickness since the second n⁺-a-Si layer 105 serves as the side wall for the semiconductor layer 103.

A drain electrode 107 and a source electrode 108 are formed on the second n⁺-a-Si layer 105. The drain electrode 107 and the source electrode 108 are formed of, for example, MoCr and has a thickness of about 200 nm. The semiconductor layer 103 at a portion where the drain electrode 107 and the source electrode 108 are opposed is a channel region. To stabilize the characteristics of the channel region, channel etching is performed and a portion of the semiconductor layer 103 is removed, for example, by a thickness of about 50 nm.

To protect the thus-formed TFT, a passivation film 109 is formed. The passivation film 109 is sometimes formed of an inorganic passivation film such as SiN or it is sometimes formed of an organic passivation film such as an acrylic resin. In addition, an inorganic passivation film and an organic passivation film are sometimes used in combination. In this example, an inorganic passivation film 109 of SiN is used. The thickness of the inorganic passivation film 109 is about 500 nm.

A through hole 110 is formed in the passivation film 109 for providing electric conduction between a pixel electrode 111 to be formed subsequently and the source electrode 108. Then, ITO, which is a transparent material for forming the pixel electrode 111, is deposited and patterned. Then, an alignment film 112 is formed covering the passivation film 109 and the pixel electrode 111. The alignment film 112 is applied with rubbing for initially aligning liquid crystal molecules.

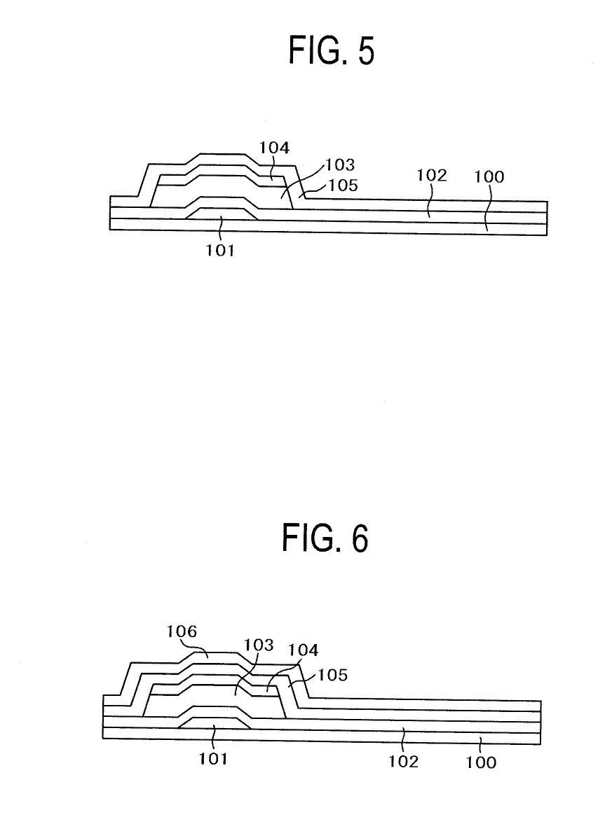

FIG. 2 to FIG. 9 are explanatory views for the process of forming the TFT substrate according to the invention. FIG. 2 is a cross sectional view showing a state in which a gate electrode 101, a gate insulating film 102, a semiconductor layer 103, and a first n⁺-a-Si layer 104 are formed above a TFT substrate 100 made of glass.

In the existent example, after the semiconductor layer 103 has been deposited by plasma CVD, the substrate is taken out of the chamber and the semiconductor layer 103 is patterned. In the present invention, after the semiconductor layer 103 has been deposited, the first n⁺-a-Si layer 104 is deposited continuously in one identical chamber.

The semiconductor layer 103 is formed of a-Si and it is formed by plasma CVD in a phosphine atmosphere. The first n⁺-a-Si layer 104 is formed by plasma CVD in a phosphorus (P)-doped phosphine atmosphere. Since the thickness of the semiconductor layer 103 is about 150 to 200 nm, the time for plasma CVD is about one minute. Since the thickness of the first n⁺-a-Si layer 104 is 10 nm, the time for plasma CVD may be 10 sec or less. Even when the first n⁺-a-Si layer 104 is formed in such a manner, the process time increases only slightly.

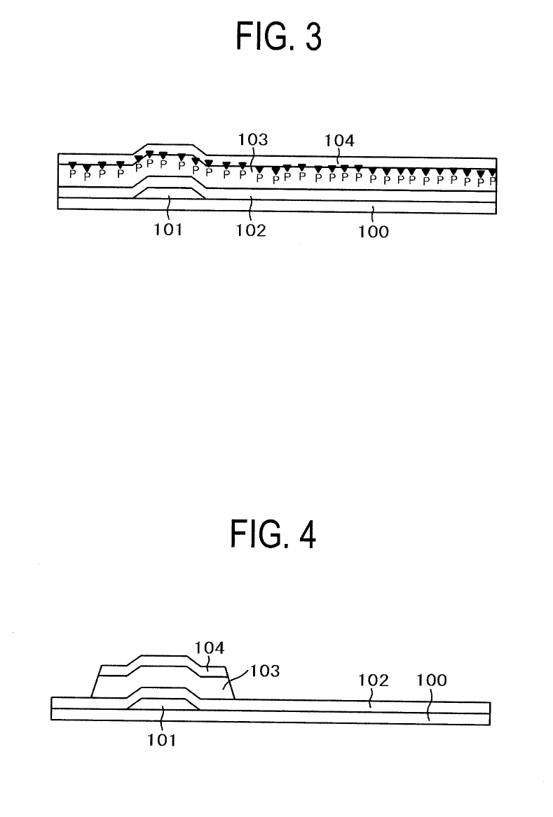

FIG. 3 shows a state where phosphorus (P) diffuses from the n⁺-a-Si layer to the surface of the semiconductor layer 103 between the thus formed semiconductor layer 103 and the first n⁺-a-Si layer 104.

Since the semiconductor layer 103 and the first n⁺-a-Si layer 104 are formed continuously, phosphorus (P) in the n⁺-a-Si layer tends to diffuse to the surface of the semiconductor layer 103. Further, diffusion of phosphorus (P) into the semiconductor layer 103 can be controlled by defining the ingredients and the amount of the first n⁺-a-Si layer 104. Accordingly, since it does not depend on the atmosphere as in usual, the ON-current characteristics can be stabilized.

After deposition of the first n⁺-a-Si layer 104, the substrate is taken out of the chamber, and the semiconductor layer 103 and the n⁺-a-Si layer 104 are patterned as shown in FIG. 4. The semiconductor layer 103 and the first n⁺-a-Si layer 104 are simultaneously patterned by using an identical mask.

After patterning of the semiconductor layer 103 and the first n⁺-a-Si layer 104, the substrate is placed in the chamber and a n⁺-a-Si layer 105 is deposited by plasma CVD. Plasma CVD for the second n⁺-a-Si layer 105 is performed in a phosphorus (P)-doped phosphine atmosphere in the same manner as that for the first n⁺-a-Si layer 104. Since the thickness of the second n⁺-a-Si layer 105 is about 25 nm, the time required for plasma CVD is about 20 sec.

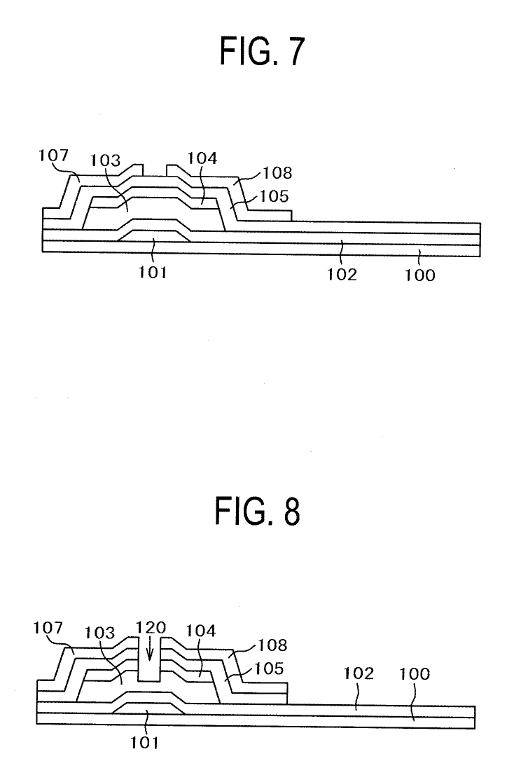

Then, as shown in FIG. 6, a metal layer 106, which will function as a drain electrode 107 or a source electrode 108, is deposited by sputtering on the second n⁺-a-Si layer 105. The metal layer 106 is formed of, for example, an MoCr alloy and has a thickness of about 200 nm. Then, as shown in FIG. 7, the metal layer 106 is patterned by photolithography to form a drain electrode 107 and a source electrode 107. Etching for the metal layer 106 is performed by wet etching.

Then, as shown in FIG. 8, the second n⁺-a-Si layer 105 is patterned by dry etching using the drain electrode 107 and the source electrode 108 as a resist. In this step, portions of the second n⁺-a-Si layer 105, the first n⁺-a-Si layer 104, and the semiconductor layer 103 are removed by dry etching from the portion corresponding to the channel region of the TFT.

Since the thickness of the second n⁺-a-Si layer 105 is 25 nm, thickness of the first n⁺-a-Si layer 104 is 10 nm, and the amount of the semiconductor layer 103 to be removed is about 50 nm, about 85 nm in total is dry etched in a portion corresponding to the channel region to form a channel etching 120.

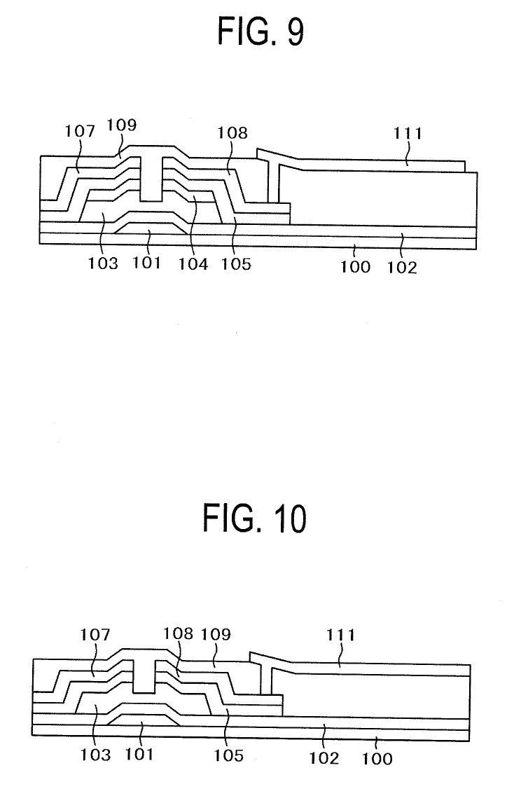

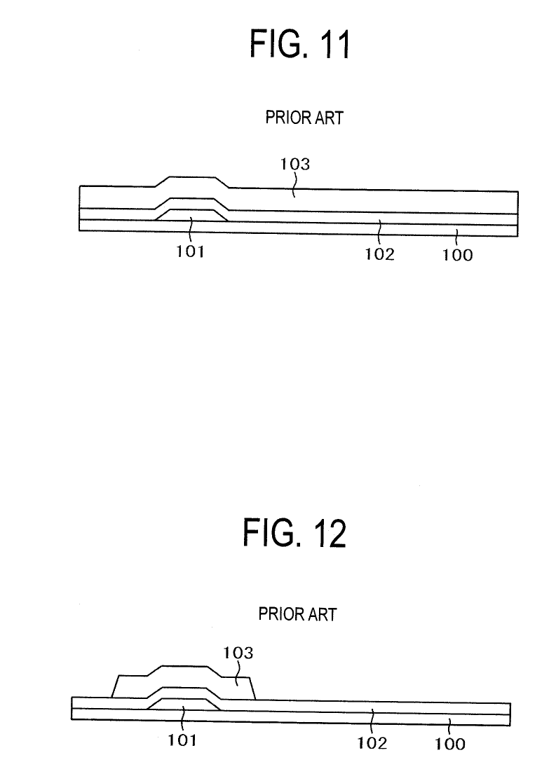

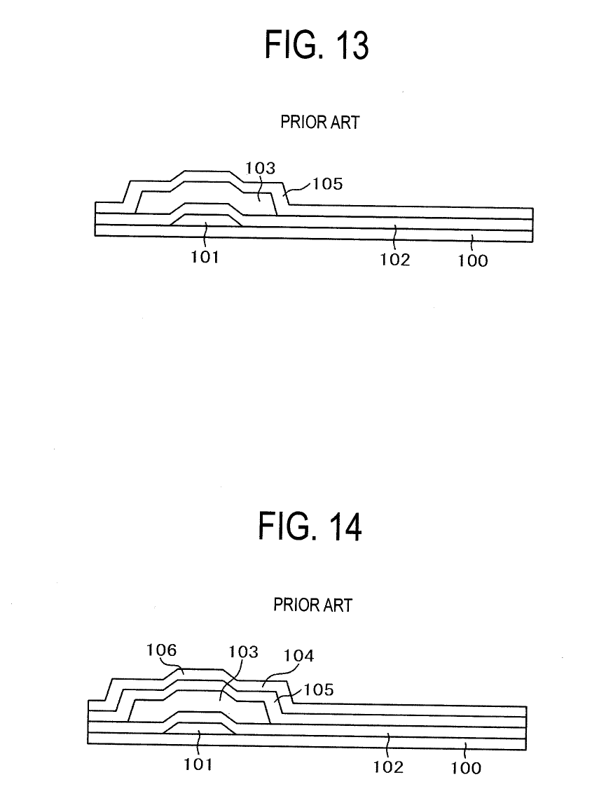

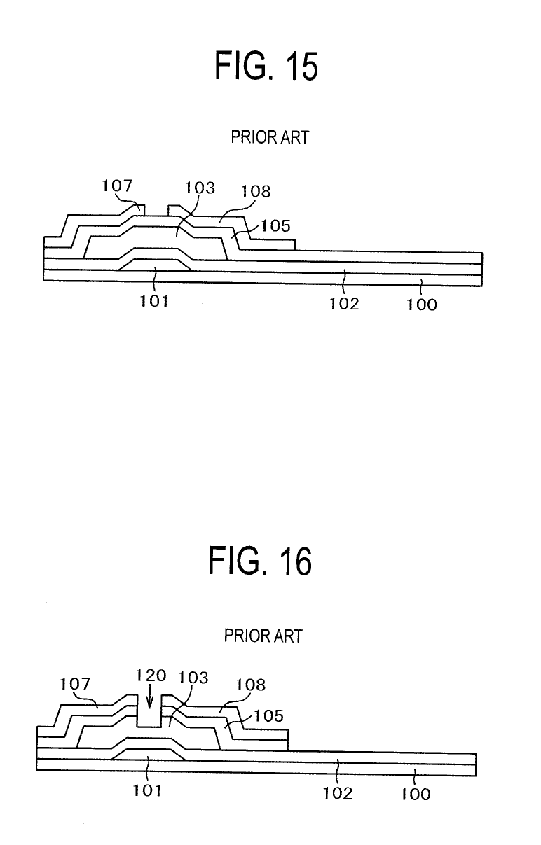

Then, an inorganic passivation film 109 comprising SiN is formed to about 500 nm thick by sputtering. A through hole 110 is formed in the passivation film 109 for providing electric conduction between the pixel electrode 111 to be formed later and the source electrode 108 of the TFT. The state is shown in FIG. 9. The passivation film 109 may be an organic passivation film or an inorganic passivation film, or they may be used in combination as in the existent example.

Then, an alignment film 112 is coated to cover the passivation film 109 and the pixel electrode 111 and then baked. The TFT substrate 100 as shown in FIG. 1 is completed by subjecting rubbing to the alignment film 112 for initially aligning liquid crystal molecules.

Subsequently, a separately formed counter substrate having a color filter, etc. disposed thereon and the TFT substrate formed as described above are bonded by means of a sealant and liquid crystals are injected between them to complete a liquid crystal display device.

Since the liquid crystal display device formed as described above has a large ON-current with less variation, the speed in writing video signals is high. Accordingly, even when the number of pixels is increased because the screen is large in size or increased in definition, images of good reproducibility can be formed.

What is claimed is:

1. A liquid crystal display device comprising:
a TFT substrate having pixels, each pixel having a pixel electrode and a TFT formed thereon;
a counter substrate; and
liquid crystals put between the TFT substrate and the counter substrate;
wherein the TFT includes
a semiconductor layer;
a first n⁺-a-Si layer formed on the semiconductor layer;
a second n⁺-a-Si layer formed to cover an upper surface of the first n⁺-a-Si layer and a side portion of the semiconductor layer; and
a drain electrode and a source electrode formed over the second n⁺-a-Si layer.

2. A liquid crystal display device according to claim 1, wherein
a thickness of the first n⁺-a-Si layer is less than a thickness of the second n⁺-a-Si layer.

3. A liquid crystal display device according to claim 1, wherein
phosphorus is doped in the first n⁺-a-Si layer and the second n⁺-a-Si layer.

4. A method of manufacturing a liquid crystal display device, the liquid crystal display device comprising
a TFT substrate having pixels, each pixel having a pixel electrode and a TFT formed thereon,
a counter substrate, and
liquid crystals put between the TFT substrate and the counter substrate,
wherein the TFT is formed by steps comprising:
forming a gate insulating film on a gate electrode which is formed on part of a glass substrate,
depositing a semiconductor layer on part of the gate insulating film by plasma CVD,
forming a first n⁺-a-Si layer continuously by plasma CVD in one identical chamber,
patterning the semiconductor layer and the first n⁺-a-Si layer, and
forming a second n⁺-a-Si layer by plasma CVD to cover the first n⁺-a-Si layer and a side portion of the semiconductor layer.

5. A method of manufacturing a liquid crystal display device according to claim 4, wherein
the method comprises further steps for forming the TFT including;
depositing a metal film which covers the second n⁺-a-Si layer by sputtering,
patterning the metal film to form a drain electrode and a source electrode of the TFT, and
patterning the second n⁺-a-Si layer by etching using the drain electrode and the source electrode as a resist.
